(19) United States
(12) Patent Application Publication
(10) Pub. No.: US 2025/0022750 A1
(43) Pub. Date: Jan. 16, 2025

(54) METHODS OF FORMING INTERCONNECT STRUCTURES

(71) Applicant: Applied Materials, Inc., Santa Clara, CA (US)

(72) Inventors: Shinjae Hwang, Santa Clara, CA (US); Yoon Ah Shin, Santa Clara, CA (US); Feng Chen, San Jose, CA (US); Bencherki Mebarki, Santa Clara, CA (US); Joung Joo Lee, San Jose, CA (US); Xianmin Tang, San Jose, CA (US)

(73) Assignee: Applied Materials, Inc., Santa Clara, CA (US)

(21) Appl. No.: 18/753,020

(22) Filed: Jun. 25, 2024

Related U.S. Application Data
(60) Provisional application No. 63/525,848, filed on Jul. 10, 2023.

(51) Int. Cl. H01L 21/768

(52) U.S. Cl. CPC H01L 21/76864; H01L 21/76834; H01L 21/76846; H01L 21/76879

(57) ABSTRACT

Embodiments of the disclosure provide methods of forming interconnect structures in the manufacture of microelectronic devices. In one or more embodiments, microelectronic devices described herein comprise at least one top interconnect structure that is interconnected to at least one bottom interconnect structure. Embodiments of the disclosure relate to methods of improving barrier layer and metal liner properties in the interconnect structures without increasing capacitance and/or damaging other layers. In some embodiments, the barrier layer is treated with microwave radiation. The treatment process can be implemented in a processing tool including a modular high-frequency emission source.

### CROSS-REFERENCE TO RELATED APPLICATIONS

This application claims priority to U.S. Provisional Application No. 63/525,848, filed Jul. 10, 2023, the entire disclosure of which is hereby incorporated by reference herein.

### TECHNICAL FIELD

Embodiments of the disclosure generally relate to methods of forming interconnect structures in microelectronic devices. More particularly, embodiments of the disclosure are directed to methods of improving barrier layer and liner properties during formation of interconnect structures in microelectronic devices.

### BACKGROUND

Microelectronic devices, such as semiconductors or integrated circuits, can include millions of electronic circuit devices such as transistors, capacitors, etc. To further increase the density of devices found on integrated circuits, even smaller feature sizes are desired. To achieve these smaller feature sizes, the size of conductive lines, vias, and interconnects, gates, etc. must be reduced. Reliable formation of multilevel interconnect structures is also necessary to increase circuit density and quality. Advances in fabrication techniques have enabled use of copper for conductive lines, interconnects, vias, and other structures. However, electromigration in interconnect structures becomes a greater hurdle to overcome, with decreased feature size and the increased use of copper for interconnections. Such electromigration may adversely affect the electrical properties of various components of the integrated circuit.

Multiple challenges impede power and performance improvements when scaling transistors and interconnects to the 3 nm node and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption. A conventional copper interconnect structure includes a barrier layer and/or a metal liner deposited on the sidewalls of gap that provide a via the sidewalls made of a dielectric material, providing good adhesion and preventing the copper from diffusing into the dielectric layer. Barrier layers can typically be the largest contributor to via resistance due to high resistivity.

Current processes include exposing the barrier layer to a plasma treatment, which reduce resistivity of the barrier layer and improve barrier layer and liner properties. However, current plasma treatments damage other layers in the interconnect, such as a low-κ dielectric layer and increase the capacitance, which degrade overall device performance.

Accordingly, there is a need for methods of improving barrier layer and liner properties without increasing capacitance and/or damaging other layers in the interconnect structure.

### SUMMARY

One or more embodiments of the disclosure are directed to a method of forming a microelectronic device. The method comprises conformally depositing a barrier layer on a semiconductor substrate; and treating the barrier layer with microwave radiation to form a treated barrier layer.

Additional embodiments of the disclosure are directed to a method of forming a microelectronic device. The method comprises conformally depositing a barrier layer on a dielectric layer on a semiconductor substrate, the dielectric layer comprising at least one feature defining a gap including sidewalls comprising a low-κ dielectric material and a bottom, the barrier layer forming in the gap along the sidewalls and the bottom; and treating the barrier layer with microwave radiation to form a treated barrier layer.

Further embodiments of the disclosure are directed to a method of forming a microelectronic device. The method comprises selectively depositing a self-assembled monolayer (SAM) on a dielectric layer on a semiconductor substrate, the dielectric layer comprising at least one feature defining a gap including sidewalls comprising a low-κ dielectric material and a bottom, the SAM selectively deposited on the bottom of the gap; conformally depositing a barrier layer in the gap along the sidewalls; treating the barrier layer with microwave radiation to form a treated barrier layer; depositing a metal liner on the treated barrier layer; removing the SAM after depositing the metal liner on the treated barrier layer; and performing a gap fill process on the metal liner.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic representation of a processing tool comprising a modular high-frequency emission source with a source array that comprises a plurality of applicators according to one or more embodiments of the disclosure;

FIG. 2 illustrates a block diagram of a modular high-frequency emission module according to one or more embodiments of the disclosure;

FIG. 3 illustrates a schematic exploded perspective view of an assembly according to one or more embodiments of the disclosure;

FIG. 4 illustrates a schematic perspective view of a source array with dielectric resonators in cavities in a dielectric plate according to one or more embodiments;

FIG. 5 illustrates a cross-sectional view of a processing tool according to one or more embodiments;

FIG. 6A illustrates a process flow diagram of a method of forming a microelectronic device according to one or more embodiments of the disclosure;

FIG. 6B illustrates a process flow diagram of a method of forming a microelectronic device according to one or more embodiments of the disclosure;

FIG. 7 illustrates a cross-sectional schematic view of a microelectronic device prior to a selective deposition process in accordance with one or more embodiments of the disclosure;

FIG. 8 illustrates a cross-sectional schematic view of the microelectronic device of FIG. 7 after formation of a blocking layer in accordance with one or more embodiments of the disclosure;

FIG. 9 illustrates a cross-sectional schematic view of the microelectronic device of FIG. 8 after formation of a barrier layer in accordance with one or more embodiments of the disclosure;

FIG. 10A illustrates a cross-sectional schematic view of the microelectronic device of FIG. 9 after treating the barrier layer to form a treated barrier layer in accordance with one or more embodiments of the disclosure;

FIG. 10B illustrates a cross-sectional schematic view of the microelectronic device of FIG. 10A after removal of the blocking layer in accordance with one or more embodiments of the disclosure;

FIG. 11 illustrates a cross-sectional schematic view of the microelectronic device of FIG. 10B after formation of a metal liner in accordance with one or more embodiments of the disclosure; and

FIG. 12 illustrates a cross-sectional schematic view of the microelectronic device of FIG. 11 after formation of a second metal layer in accordance with one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate surface” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Some embodiments of the disclosure provide methods for improving performance of interconnects. Interconnects comprise metal lines that transfer current within the same device layer, and metal vias that transfer current between layers. These lines and vias are formed with conductive metal such as copper or cobalt in gaps formed within the device. In one or more embodiments, a dielectric layer comprises at least one feature defining a gap including sidewalls and a bottom. In one or more embodiments, the gap comprises the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate.

Embodiments of the disclosure advantageously provide methods for improving barrier layer and liner properties for interconnect structures, such as copper interconnect structures. One or more embodiments of the disclosure advantageously provide methods for improving barrier layer and liner properties for interconnect structures without using plasma. Specific embodiments advantageously provide methods for improving barrier layer and liner properties that do not damage other layers in the structure, such as a low-κ dielectric layer.

Embodiments of the disclosure provide an assembly for a processing tool. In one or more embodiments, the assembly comprises a source array and a housing. In an embodiment, the source array comprises a dielectric plate, a plurality of cavities extending into the dielectric plate, and a plurality of dielectric resonators in each of the cavities. In one or more embodiments, a width of the dielectric resonator is smaller than a width of the cavity so that a gap separates a sidewall of the dielectric resonator from a sidewall of the cavity. In one or more embodiments, the housing comprises a conductive body, and an opening through the conductive body. The dielectric resonator may be within the opening. In one or more embodiments, the housing further comprises a conductive ring in the gap separating the sidewall of the dielectric resonator from the sidewall of the cavity.

Embodiments of the disclosure provide methods of forming interconnect structures in the manufacture of microelectronic devices. In one or more embodiments, microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

Embodiments of this disclosure utilize a microwave process. Advantageously, the energy of the microwaves can be tuned low enough that it does not substantially damage dielectric materials (e.g., no plasma and/or low temperature). Further, the disclosed methods are self-limiting by only affecting the barrier layer and metal liner and not the other layers, such as a dielectric layer, in the structures.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

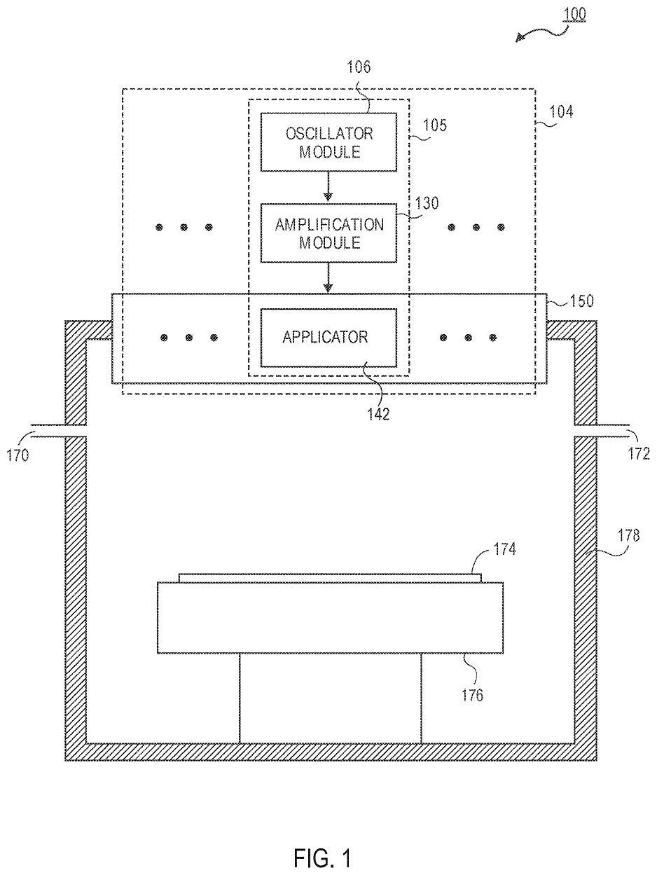

FIG. 1 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma enhanced atomic layer deposition (PEALD), etch and selective removal processes, and plasma cleaning. Additional embodiments may include a processing tool 100 that utilizes high-frequency electromagnetic radiation without the generation of a plasma (e.g., microwave heating, etc.). As used herein, “high-frequency” electromagnetic radiation includes radio frequency radiation, very-high-frequency radiation, ultra-high-frequency radiation, and microwave radiation. “High-frequency” may refer to frequencies between 0.1 MHz and 300 GHz.

The processing tool 100 includes a semiconductor processing chamber 178. In one or more embodiments, the semiconductor processing chamber 178 is a vacuum chamber. A vacuum chamber may include a pump (not shown) for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through a source array 150 (e.g., as a showerhead) for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alter-native embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. As shown, the applicators 142 are schematically shown as being integrated into the source array 150. The skilled artisan will appreciate that the disclosure is not limited to the applicators 142 being integrated into the source array 150.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130. In one or more embodiments, the plurality of oscillator modules 106 may generate incoherent electromagnetic radiation. Accordingly, the electromagnetic radiation induced in the semiconductor processing chamber 178 will not interact in a manner that results in an undesirable interference pattern.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

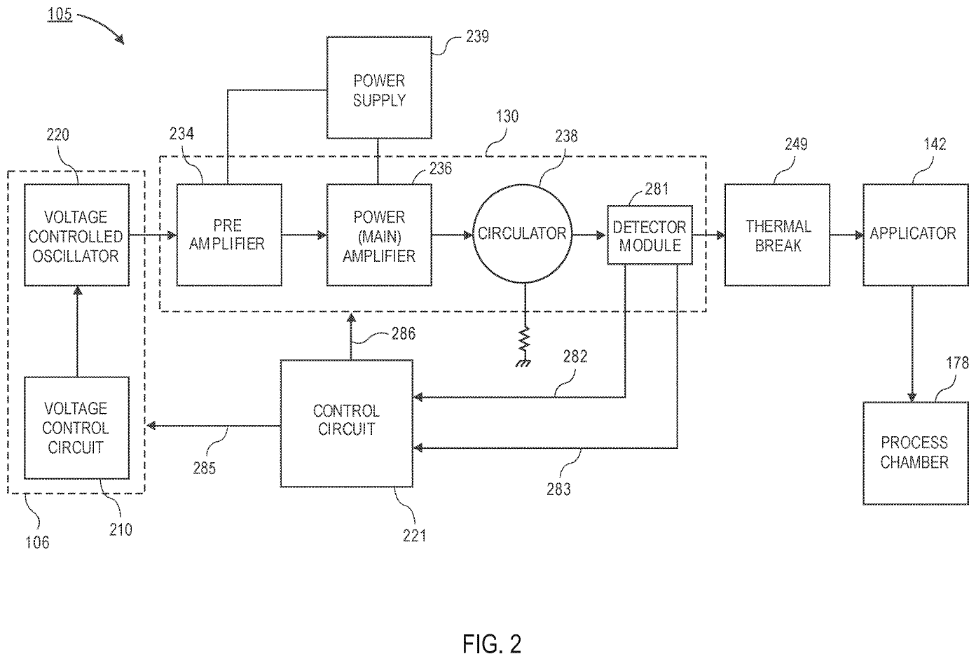

FIG. 2 illustrates a block diagram of a high-frequency emission module 105. In one or more embodiments, the high-frequency emission module 105 comprises an oscillator module 106. The oscillator module 106 may include a voltage control circuit 210 for providing an input voltage to a voltage controlled oscillator 220 in order to produce high-frequency electromagnetic radiation at a desired frequency. One or more embodiments include an input voltage in a range of from 1 V to 10V of DC. In one or more embodiments, the voltage controlled oscillator 220 is an electronic oscillator whose oscillation frequency is controlled by the input voltage. According to one or more embodiments, the input voltage from the voltage control circuit 210 results in the voltage controlled oscillator 220 oscillating at a desired frequency. In some embodiments, the high-frequency electromagnetic radiation has a frequency in a range of from about 0.1 MHz to about 30 MHz. In some embodiments embodiment, the high-frequency electromagnetic radiation has a frequency in a range of from about 30 MHz to about 300 MHz. In some embodiments, the high-frequency electro-magnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage controlled oscillator 220 to an amplification module 130. The amplification module 130 may include a driver/pre-amplifier 234, and a main power amplifier 236 that are each coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249. In specific embodiments, such as, for example, embodiments that do not include the use of plasma and include use of electromagnetic radiation, the feedback control of the oscillator module 106 and the amplification module 130, in addition to the tailoring of the impedance matching in the thermal break 249 may allow for the level of the reflected power to be less than or equal to 50% of the forward power.

Accordingly, embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

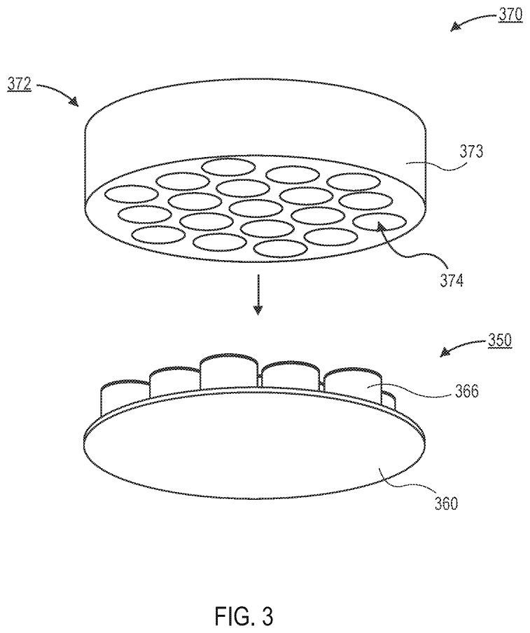

Referring now to FIG. 3, a schematic exploded perspective view of an assembly 370 is shown. The assembly 370 comprises a source array 350 and a housing 372. As indicated by the arrows, the housing 372 fits over and around the source array 350. In the illustrated embodiment, the assembly 370 is shown as having a substantially circular shape. However, the skilled artisan will appreciate that the assembly 370 may have any suitable shape such as polygonal, elliptical, wedge shaped, or the like. In some embodiments, the source array 350 comprises a dielectric plate 360 and a plurality of dielectric resonators 366 on the dielectric plate 360. In some embodiments, the dielectric plate 360 and the plurality of dielectric resonators 366 are a monolithic structure. That is, in embodiments where the dielectric plate 360 and the plurality of dielectric resonators 366 are a monolithic structure, there is no physical interface between a bottom of the dielectric resonators 366 and the dielectric plate 360. As used herein, a “physical interface” refers to a first surface of a first discrete body contacting a second surface of a second discrete body.

In other embodiments, the dielectric plate 360 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the source array 350 comprises a dielectric material. For example, the source array 350 may be a ceramic material. In some embodiments, one suitable ceramic material that may be used for the source array 350, as an example, is aluminum oxide (Al₂O₃). In specific embodiments where the dielectric plate 360 and the plurality of dielectric resonators 366 are a monolithic structure, the monolithic structure may be fabricated from a single block of material. In other embodiments, a rough shape of the monolithic source array 350 may be formed with a molding process, and subsequently machined to provide the final structure with the desired dimensions. For example, green state machining and firing may be used to provide the desired shape of the monolithic source array 350. In the illustrated embodiment, the dielectric resonators 366 are shown as having a circular cross-section (when viewed along a plane parallel to the dielectric plate 360). However, the skilled artisan will appreciate that the dielectric resonators 366 may comprise many different cross-sections. For example, the cross-section of the dielectric resonators 366 may have any shape that is centrally symmetric.

In one or more embodiments, the housing 372 comprises a conductive body 373. The conductive body may include any suitable conductive material. For example, the conductive body 373 may be aluminum or the like. The housing comprises a plurality of openings 374. The openings 374 may pass entirely through a thickness of the conductive body 373. The openings 374 may be sized to receive the dielectric resonators 366. For example, as the housing 372 is displaced towards the monolithic source array 350 (as indicated by the arrow) the dielectric resonators 366 will be inserted into the openings 374.

In the illustrated embodiment of FIG. 3, the housing 372 is shown as a single conductive body 373. However, the skilled artisan will appreciate that the housing 372 may comprise one or more discrete conductive components. The discrete components may be individually grounded, or the discrete components may be joined mechanically or by any form of metallic bonding, to form a single electrically conductive body 373.

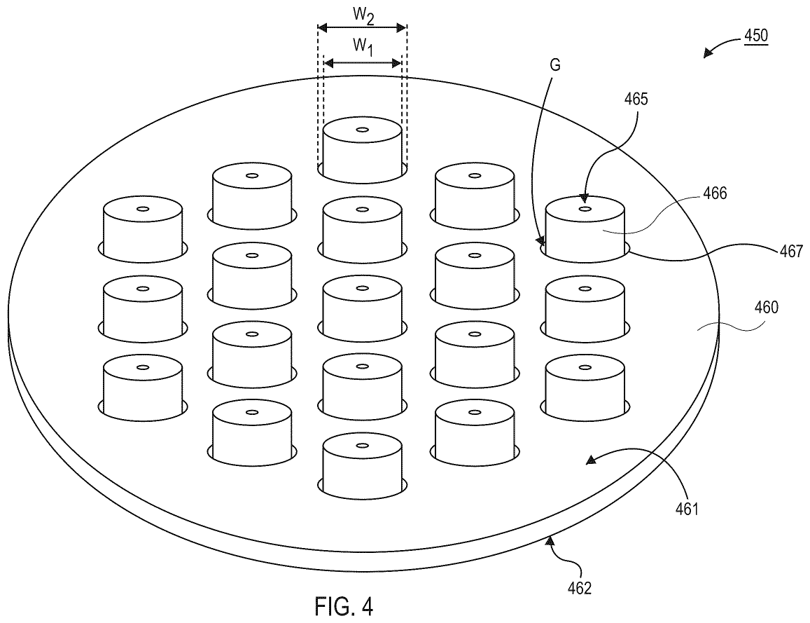

FIG. 4 illustrates a schematic perspective view of a source array 450. In one or more embodiments, the source array 450 comprises the same components and features as the source array 350 shown in FIG. 3. Accordingly, unless provided otherwise, the source array 350 and source array 450 may be described interchangeably.

In FIG. 4, the source array 450 comprises a dielectric plate 460. A plurality of cavities 467 are disposed into a first surface 461 of the dielectric plate 460. The cavities 467 do not pass through to a second surface 462 of the dielectric plate 460. Stated differently, the cavities 467 do not pass through a thickness of the dielectric plate 460. The source array 450 may further include a plurality of dielectric resonators 466. Each of the dielectric resonators 466 may be in a different one of the cavities 467.

In embodiments where the dielectric plate 460 and the plurality of dielectric resonators 466 are a monolithic structure, the bottom of the cavity 467 is entirely outside a perimeter defined by the sidewalls of the dielectric resonators 466. In some embodiments, the cavity 467 may be referred to as a groove into the first surface 461 that surrounds the dielectric resonator 466.

The monolithic configuration results in the cavity 467 being a ring shape. Part of the cavity 467 is defined by the sidewall of the dielectric resonator 466. More particularly, an interior surface of the ring cavity 467 is defined by the sidewall of the dielectric resonator 466 and an outer surface of the ring cavity 467 is defined by a portion of the dielectric plate 460.

In some embodiments, each of the dielectric resonators 466 independently comprises a hole 465 in the axial center of the dielectric resonator 466. In one or more embodiments, the hole 465 is sized to accommodate a monopole antenna (not shown). In one or more unillustrated embodiments, the hole 465 extends down into the body of the dielectric resonator 466. In some embodiments, a bottom of the hole 465 is below (in the Z-direction) the first surface 461 of the dielectric plate 460. Stated differently, in embodiments where the bottom of the hole 465 is below (in the Z-direction) the first surface 461 of the dielectric plate 460, the bottom of the hole 465 is within the cavity 467. In some embodiments, a bottom of the hole 465 is at or above (in the Z-direction) the first surface 461 of the dielectric plate 460.

In one or more embodiments, the dielectric resonators 466 may have a first width W₁ and the cavities 467 may have a second width W₂. In some embodiments, the first width W₁ of the dielectric resonators 466 is smaller than the second width W₂ of the cavities 467. The difference in the widths provides a gap G between a sidewall of the dielectric resonators 466 and a sidewall of the cavities 467. In the illustrated embodiment of FIG. 4, each of the dielectric resonators 466 are shown as having a uniform width W₁. However, the skilled artisan will appreciate that not all dielectric resonators 466 of the source array 450 need to have the same dimensions.

In one or more unillustrated embodiments, the source array 450 includes a conductive layer disposed over the surfaces of the source array 450.

In one or more unillustrated embodiments, the source array 350, 450 includes one or more rings configured to separate the sidewall of the opening 374 in the housing 372 from the sidewall of the dielectric resonator 466. In such embodiments, the rings fill the gap G between the sidewall of the dielectric resonator 466 and the sidewall of the cavity 467 into the dielectric plate 460. That is, a portion of the ring extends below (in the Z-direction) the first surface 461 of the dielectric plate 460. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the source array 350, and provides improved coupling of the high-frequency electromagnetic radiation into the processing chamber, such as semiconductor processing chamber 178.

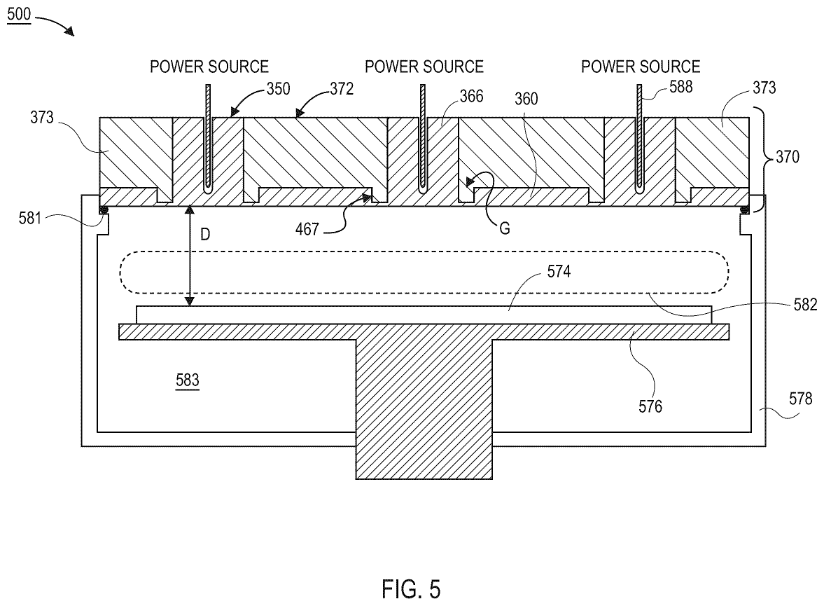

FIG. 5 illustrates a cross-sectional view of a processing tool 500 according to one or more embodiments. In one or more embodiments, the processing tool 500 comprises a semiconductor processing chamber 578 that is sealed by an assembly 370. For example, the assembly 370 may rest against one or more o-rings 581 to provide a vacuum seal to an interior volume 583 of the semiconductor processing chamber 578. In other embodiments, the assembly 370 may interface with the semiconductor processing chamber 578. That is, the assembly 370 may be part of a lid that seals the semiconductor processing chamber 578. In some embodiments, the processing tool 500 may comprise a plurality of processing volumes (which may be fluidically coupled together), with each processing volume having a different assembly 370.

In some embodiments, a chuck 576 or the like may support a workpiece 574 (e.g., wafer, substrate, etc.). In some embodiments, the chamber volume 583 may be suitable for striking a plasma 582. That is, the semiconductor processing chamber 578 may be a vacuum chamber.

In one or more embodiments, the assembly 370 shown in FIG. 3 comprises the source array 350 and the housing 372. As stated elsewhere herein, unless provided otherwise, the source array 350 and source array 450 may be described interchangeably.

In some embodiments, monopole antennas 588 may extend into holes 365 in the dielectric resonators 366. The monopole antennas 588 are each electrically coupled to power sources (e.g., high-frequency emission modules 105).

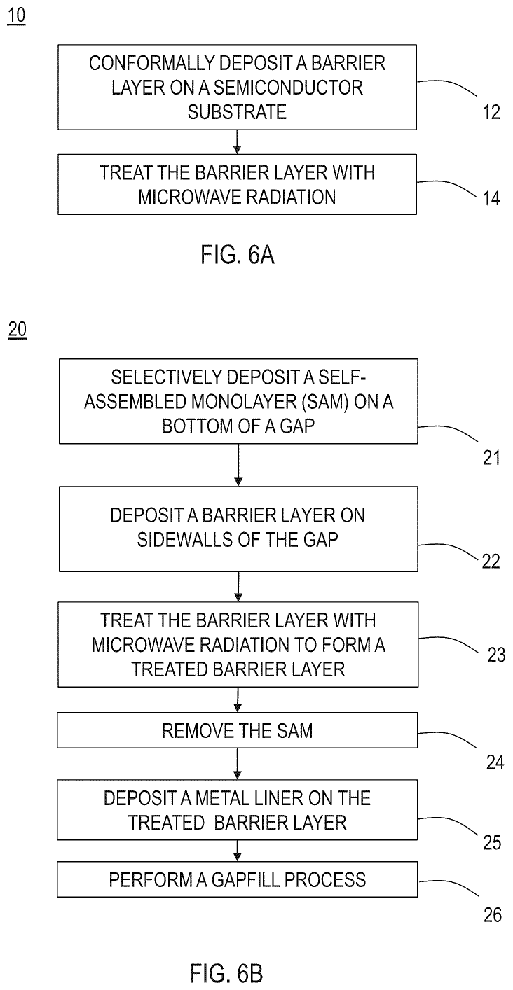

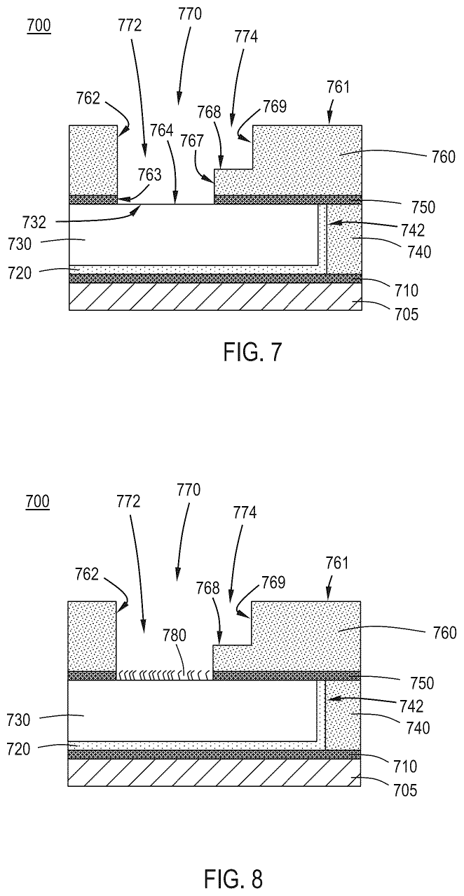

Methods of forming microelectronic devices are described herein with reference to FIGS. 6A-6B and FIGS. 7-12. FIGS. 6A and 6B illustrate process flow diagram of methods of forming microelectronic devices, such as the microelectronic devices 700 shown in FIGS. 7-12. The methods of forming microelectronic devices described herein may be implemented in any of the processing tools described herein, such as the illustrated and unillustrated embodiments described above with respect to FIGS. 1-5.

In FIG. 6A, method 10 comprises conformally depositing a barrier layer on a semiconductor substrate (operation 12) and treating the barrier layer with microwave radiation (operation 14). In one or more embodiments, the method 10 comprises conformally depositing a barrier layer on a dielectric layer on a semiconductor substrate (operation 12), the dielectric layer comprising at least one feature defining a gap including sidewalls comprising a low-κ dielectric material and a bottom, the barrier layer forming in the gap along the sidewalls and the bottom; and treating the barrier layer with microwave radiation to form a treated barrier layer (operation 14).

In FIG. 6B, method 20 comprises selectively depositing a self-assembled monolayer (SAM) on a dielectric layer on a semiconductor substrate, the dielectric layer comprising at least one feature defining a gap including sidewalls comprising a low-κ dielectric material and a bottom, the SAM selectively deposited on the bottom of the gap (operation 21); conformally depositing a barrier layer in the gap along the sidewalls (operation 22); treating the barrier layer with microwave radiation to form a treated barrier layer (operation 23); removing the SAM after treating the barrier layer to form the treated barrier layer (operation 24); depositing a metal liner on the treated barrier layer (operation 25); and performing a gapfill process on the metal liner (operation 26).

The microelectronic device 700 illustrated in FIG. 7 has a substrate 705 with a first layer 710 formed thereon. Substrate 705 can be any suitable substrate material for use with a microelectronic device. In some embodiments, the substrate 705 is a semiconductor substrate. In some embodiments, the substrate 705 can include additional layers of dielectrics, metals, etch stop layers and semiconductor layers including underlying circuits (e.g., transistors, capacitors) that have been formed in prior processes.

Those skilled in the art will understand that the use of ordinals such as “first” and “second” to describe different layers or films does not imply a specific location or number within the microelectronic device, or order an order of formation. A “second” layer of a material can be formed without a “first” layer being present. The ordinals are used for descriptive purposes when referring to the Figures.

The first layer 710 is an optional layer. In some embodiments, the first layer 710 is omitted. In some embodiments, the first layer 710 is made up of a lamination of more than one layer. The first layer 710 can have any suitable function including, but not limited to, acting as an etch stop layer for previous or future microelectronic device manufacturing operations.

A first dielectric layer 740 is formed on a portion of the first layer 710. The first dielectric layer 740 has an inner sidewall 742 which defines a boundary of the first dielectric layer 740, leaving an opening. The opening can be, for example, a trench for a first metallization layer of the microelectronic device 700.

The first dielectric layer 740 can be any suitable material formed by any suitable technique known to the skilled artisan. In some embodiments, the first dielectric layer 740 comprises one or more of an oxide or a nitride. In some embodiments, the first dielectric layer 740 comprises silicon oxide. The first dielectric layer 740 of some embodiments is deposited by one or more of chemical vapor deposition (CVD), atomic layer deposition (ALD), plasma-enhanced chemical vapor deposition (PECVD), plasma-enhanced atomic layer deposition (PEALD), physical vapor deposition (PVD), or spin-on techniques.

The dielectric surface of the first dielectric layer 740 on the substrate 705 may comprise any suitable dielectric materials. Suitable dielectric materials include, but are not limited to, oxides (e.g., silicon oxides), low-κ dielectric materials, and high-k dielectric materials. In some embodiments, the dielectric surface consists essentially of silicon oxide. As used in this manner, the term “consists essentially of” means that the surface is greater than or equal to about 95%, 98% or 99% of the stated material, on an area basis. In some embodiments, the first dielectric layer 740 comprises one or more of silicon oxide (SiO₂), silicon nitride (SiN), silicon carbooxynitride (SiCON), silicon oxycarbide (SiOC), aluminum oxide (AlOx), or aluminum nitride (AlNx).

In some embodiments, a liner 720 is formed on the top surface of the first layer 710 and abutting the inner sidewall 742 of the first dielectric layer 740. The liner 720 of some embodiments acts as one or more of an adhesion layer, barrier layer, or liner. The liner 720 can be any suitable material, including, but not limited to, oxides and nitrides. The liner 720 can be formed by any suitable technique known to the skilled artisan. In some embodiments, the liner 720 is formed as a conformal film by atomic layer deposition (ALD).

In some embodiments, a first metal layer 730 is formed on the liner 720 and forms a first metallization layer. The first metal layer 730 can be any suitable material known to the skilled artisan deposited by any suitable technique. Suitable metal materials include, but are not limited to, metals, metal nitrides, metal alloys, and other conductive materials. In some embodiments, the first metal layer 730 comprises one or more of copper (Cu), cobalt (Co), tungsten (W), molybdenum (Mo), ruthenium (Ru) or titanium nitride (TiN). In some embodiments, the first metal layer 730 consists essentially of cobalt (Co). In some embodiments, the first metal layer 730 consists essentially of tungsten (W). In some embodiments, the first metal layer 730 consists essentially of titanium nitride (TiN).

In some embodiments, an etch stop layer 750 is formed on the first metal layer 730. The etch stop layer 750 can be any suitable material formed by any suitable technique known to the skilled artisan.

In some embodiments, the etch stop layer 750 comprises one or more of aluminum oxide (AlOx), aluminum oxide (Al₂O₃), or aluminum nitride (AlNx). In some embodiments, the etch stop layer 750 consists of one or more of aluminum oxide (AlOx), aluminum oxide (Al₂O₃), or aluminum nitride (AlNx). In some embodiments, the etch stop layer 750 comprises aluminum oxide (AlOx). In some embodiments, the etch stop layer 750 consists of aluminum oxide (AlOx). In some embodiments, the etch stop layer 750 comprises aluminum oxide (Al₂O₃). In some embodiments, the etch stop layer 750 consists of aluminum oxide (Al₂O₃). In some embodiments, the etch stop layer 750 comprises aluminum nitride (AlNx). In some embodiments, the etch stop layer 750 consists of aluminum nitride (AlNx).

In some embodiments, a second dielectric layer 760 is formed on the etch stop layer 750. The second dielectric layer 760 can be any suitable material formed by any suitable technique known to the skilled artisan. In some embodiments, the second dielectric layer 760 comprises one or more of an oxide or a nitride. In some embodiments, the second dielectric layer 760 comprises a low-κ dielectric material. In some embodiments, the second dielectric layer 760 comprises silicon oxide. The second dielectric layer 760 of some embodiments is deposited by one or more of chemical vapor deposition (CVD), atomic layer deposition (ALD), plasma-enhanced chemical vapor deposition (PECVD), plasma-enhanced atomic layer deposition (PEALD), physical vapor deposition (PVD), or spin-on techniques.

The second dielectric layer 760 comprises a different material than the etch stop layer 750. The dielectric surface of the second dielectric layer 760 may comprise any suitable dielectric materials. Suitable dielectric materials include, but are not limited to, oxides (e.g., silicon oxides), low-κ dielectric materials, and high-k dielectrics. In some embodiments, the dielectric surface consists essentially of silicon oxide. In some embodiments, the second dielectric layer 760 comprises one or more of silicon oxide (SiO₂), silicon nitride (SiN), silicon carbooxynitride (SiCON), silicon oxycarbide (SiOC), aluminum oxide (AlOx), aluminum oxide (Al₂O₃) or aluminum nitride (AlNx). In some embodiments, the second dielectric layer 760 comprises the same material as the first dielectric layer 740. In some embodiments, the second dielectric layer 760 comprises a different material than the first dielectric layer 740.

The substrate 705 comprising the second dielectric layer 760, etch stop layer 750 and first metal layer 730 has a feature 770 formed therein. The feature 770 is formed in the second dielectric layer 760 and the etch stop layer 750 exposing a top surface 732 of the first metal layer 730. The feature 770 illustrated has a via portion 772 and a trench portion 774.

The via portion 772 extends through the second dielectric layer 760 and the etch stop layer 750 to the first metal layer 730. The via portion 772 exposes a top surface 732 of the first metal layer 730. The top surface 732 of the first metal layer 730 forms a bottom surface 764 of the via portion 772. The via portion 772 is bounded on one side by the sidewall 762 of the second dielectric layer 760 and the sidewall 763 of the etch stop layer 750. The via portion 772 is bounded on another side by a lower sidewall 767 of the second dielectric layer 760 and the sidewall 763 of the etch stop layer 750. The skilled artisan will recognize that the via portion 772 may have a circular cross-section and that the use of a first side and a second side (e.g., one side and another side) to describe the via portion 772 is for descriptive purposes based on the cross-sectional views in the Figures. When the via portion 772 is a cylindrical hole, the sidewalls of the dielectric layer and the etch stop layer are continuous so that there is effectively a single sidewall, rather than a first side and second side (e.g., one side and another side) that appears in the cross-section.

The trench portion 774 has a bottom surface 768 formed from the second dielectric layer 760 and is bounded on one side by upper sidewall 769 which comprises the second dielectric layer 760. The trench portion 774 has an open side where the via portion 772 passes through the second dielectric layer 760 and etch stop layer 750.

The portion of the feature 770 not bounded by the via portion 772 and the trench portion 774 can be collectively referred to as a gap.

The embodiment illustrated in FIG. 7 is the substrate 705 for further deposition processes. The etch stop layer 750 in the illustrated embodiment is one or more of aluminum oxide or aluminum nitride, and the surface (sidewall 763) of the etch stop layer 750 is one or more of an aluminum oxide surface or an aluminum nitride surface. For the avoidance of doubt, no stoichiometric ratios are implied by the identification of materials disclosed herein, unless the context provides otherwise. For example, an aluminum oxide (AlOx) material contains aluminum and oxygen, and an aluminum nitride (AlNx) material contains aluminum and nitrogen. These elements may or may not be present at a 1:1 ratio.

The substrate 705 has a metal surface (the bottom surface 764 of the via portion 772), a dielectric surface (sidewall 762, lower sidewall 767, bottom surface 768, upper sidewall 769, and top surface 761) and one or more of an aluminum oxide surface, such as an aluminum oxide (Al₂O₃) surface or an aluminum nitride surface (sidewall 763 of etch stop layer 750).

In some embodiments, the dielectric surface (sidewall 762, lower sidewall 767, bottom surface 768, upper sidewall 769, and top surface 761) is substantially undamaged by the methods 10, 20. As used in this regard, the dielectric is “substantially undamaged” if the normalized loss of carbon/silicon is less than or equal to about 30%.

FIG. 8 illustrates the microelectronic device 700 of FIG. 7 after selectively depositing a blocking layer 780. Specifically, FIG. 8 illustrates operation 21 of method 20 (selectively depositing a blocking layer or self-assembled monolayer (SAM)) on a bottom of a gap.

It was discovered that use of a blocking molecule to deposit the blocking layer 780 improved interconnect via resistance by minimizing via bottom barrier layer growth on via sidewall rather than via bottom. Selection of blocking molecule chemistry enables metal nucleation and growth only at via sidewall, not on the via bottom. Thinner or no metal growth on via bottom reduces via resistance and metal corrosion. In specific embodiments, a blocking molecule chemistry/process advantageously suppresses metal liner growth at the via bottom (for example, less than 10 Angstroms, less than 5 Angstroms, less than 4 Angstroms, less than 3 Angstroms, less than 2 Angstroms, or less than 1 Angstrom) and maintain barrier layer and/or metal liner growth at via sidewall (for example, 5 Angstroms or greater or 10 Angstroms or greater). The use of the blocking molecule to form blocking layer 780 at operation 21 advantageously achieves selectivity of subsequent metal deposition on a via sidewall relative to a via bottom.

The substrate 705 comprising the metal surface (the bottom surface 764 of the via portion 772), the dielectric surface (sidewall 762, lower sidewall 767, bottom surface 768, upper sidewall 769, and top surface 761) and one or more of the aluminum oxide surface, such as Al₂O₃, or the aluminum nitride surface (sidewall 763 of etch stop layer 750) is exposed to a blocking molecule, to form the blocking layer 780. The blocking layer 780 forms selectively on the metal surface (the bottom surface 764 of the via portion 772) over the dielectric surface (sidewall 762, lower sidewall 767, bottom surface 768, upper sidewall 769, and top surface 761) and the aluminum oxide surface or the aluminum nitride surface. In some embodiments, the blocking molecule used to deposit the blocking layer 780 comprises any suitable blocking molecule known to the skilled artisan.

In some embodiments, the blocking layer 780 is selectively formed on the metal surface (the bottom surface 764 of the via portion 772), over the dielectric surface (sidewall 762, lower sidewall 767, bottom surface 768, upper sidewall 769, and top surface 761) and one or more of the aluminum oxide surface or the aluminum nitride surface (sidewall 763 of etch stop layer 750). As used in this specification and the appended claims, the phrase “selectively over”, or similar, means that the subject material is deposited on the stated surface to a greater extent than on another surface. In some embodiments, “selectively” means that the subject material forms on the selective surface at a rate greater than or equal to 2×, 5×, 10×, 15×, 20×, 25×, 30×, 35×, 40×, 45× or 50× the rate of formation on the non-selected surface.

The dielectric surface of the substrate may comprise any suitable dielectric materials. Suitable dielectric materials include, but are not limited to, oxides (e.g., silicon oxides), low-k dielectric materials and high-k dielectrics. In some embodiments, the dielectric surface consists essentially of silicon oxide. As used in this manner, the term “consists essentially of” means that the surface is greater than or equal to about 95%, 98% or 99% of the stated material, on an area basis.

The metal surface of the substrate may comprise any suitable metal materials. Suitable metal materials include, but are not limited to, metals, metal nitrides, metal alloys, and other conductive materials. In some embodiments, the metal surface comprises one or more of cobalt, tungsten, molybdenum, or titanium nitride. In some embodiments, the metal surface consists of cobalt. In some embodiments, the metal surface consists of tungsten. In some embodiments, the metal surface consists of molybdenum. In some embodiments, the metal surface consists of titanium nitride.

In some embodiments, forming the blocking layer 780 comprises exposing soaking the substrate in the blocking molecule. In some embodiments, forming the blocking layer 780 comprises exposing the substrate to pulses of the blocking chemistry. The pulses of blocking chemistry can be any suitable duration and occur any suitable number of times. In some embodiments, during formation of the blocking layer 780 occurs with greater than 1, 10, 100, 250, 500 or 1000 pulses of blocking layer chemistry. In some embodiments, the total time for exposure to the blocking chemistry is greater than 1 second, 10 seconds, 100 seconds, 500 seconds or 1000 seconds.

As the technology node advances, for example, when scaling microelectronic devices and interconnects to the 3 nm node and beyond the back end of line (BEOL) includes new interfaces such as tungsten (W), molybdenum (Mo), and ruthenium (Ru). Improving blocking molecule (e.g., self-assembled monolayer (SAM)) selectivity on metal to low-κ surfaces becomes more challenging, especially when these interfaces contain different kinds of impurities such as oxygen, carbon, nitrogen, fluorine, chlorine, etc. It has been determined that the pre-clean before SAM processes further improves blocking molecule (SAM) selectivity. Pre-cleaning helps control damage to low-κ dielectric materials.

In some embodiments, the substrate 705 is cleaned prior to exposing the substrate 705 to the blocking molecule. In some embodiments, only the metal surface of the substrate is cleaned prior to exposing the substrate to the blocking molecule. In some embodiments, the substrate or the metal surface of the substrate is cleaned with a hydrogen plasma. In some embodiments, the hydrogen plasma is a conductively coupled plasma (CCP). In some embodiments, the hydrogen plasma is an inductively coupled plasma (ICP). In some embodiments, the hydrogen plasma is formed by a remote plasma source. In some embodiments, the hydrogen plasma comprises plasma of H₂. In some embodiments, the hydrogen plasma comprises or consists essentially of a combination of argon (Ar) and hydrogen (H₂). In some embodiments, the hydrogen plasma comprises or consists essentially of a combination of helium (He) and hydrogen (H₂).

The blocking layer 780 is formed at a temperature that is favorable to close packing of the self-assembled monolayer of blocking chemistry species. In some embodiments, the substrate 705 is maintained at a temperature in the range of 100° C. to 500° C., or in the range of 150° C. to 500° C., or in the range of 200° C. to 400° C., or in the range of 225° C. to 350° C., or in the range of 250° C. to 350° C., or in the range of 250° C. to 300° C.

Some embodiments of the disclosure are directed to selective deposition of barrier layers on dielectric surfaces relative to metal surfaces. Selective barrier layers (e.g., tantalum nitride) can reduce the RC delay by greater than or equal to 50%. Current processes deposit TaN selectively on copper using known SAMs for the N3 technology node. For next generation devices, selective deposition of tantalum nitride on dielectric surfaces relative to tungsten metal is desired.

Embodiments of the disclosure advantageously provide methods for surface pretreatment, such as selective blocking of metal surfaces (including but are not limited to copper, cobalt, tungsten, tantalum, tantalum nitride, tantalum oxide, titanium, titanium oxide, titanium nitride, ruthenium, ruthenium oxide and iridium etc.). Some embodiments advantageously provide methods to selectively grow a barrier material on a dielectric surface such as silicon oxide (SiOₓ), silicon nitride (SiN), silicon carboxynitride (SiCON), silicon oxycarbide (SiCO), etc., by using a selective blocking chemistry (e.g., a self-assembled monolayer (SAM)).

Pre-cleaning of the substrate can occur at any suitable temperature depending on, for example, the cleaning technique. In some embodiments, pre-cleaning of the substrate occurs at a temperature in a range of from 150° C. to 500° C., such as in a range of from 200° C. to 400° C.

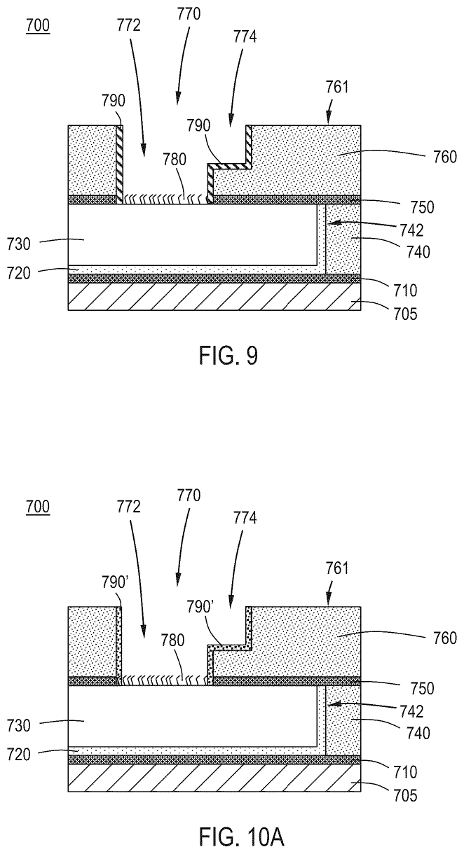

FIG. 9 illustrates the microelectronic device 700 of FIG. 7 after formation of a barrier layer 790 on the surfaces of the second dielectric layer 760 and etch stop layer 750.

In some embodiments, the barrier layer 790 comprises one or more of tantalum nitride (TaN), titanium nitride (TiN), silicon nitride (SiN), titanium silicon nitride (TiSiN), tantalum silicon nitride (TaSiN) or silicon oxynitride (SiON).

In some embodiments, the barrier layer 790 comprises, consists essentially of, or consists of doped or undoped tantalum nitride (TaₓN_{y}). For the avoidance of doubt, no stoichiometric ratios are implied by the identification of materials disclosed herein, unless the context provides otherwise. In some embodiments, the tantalum nitride (TaN) is deposited by a thermal atomic layer deposition (ALD) process. As used in this manner, a thermal process does not include a plasma. In some embodiments, the tantalum nitride is deposited using pentakis (dimethylamino) tantalum (PDMAT) and ammonia in a thermal ALD process.

In one or more embodiments, the barrier layer 790 comprises, consists essentially of, or consists of doped tantalum nitride (TaₓN_{y}). In some embodiments, the barrier layer 790 comprises tantalum nitride (TaₓN_{y}) doped with one or more of ruthenium (Ru), cobalt (Co), molybdenum (Mo), tungsten (W), or iridium (Ir).

In some embodiments, the barrier layer 790 comprises, consists essentially of, or consists of doped or undoped titanium nitride (TixNy). In some embodiments, the tantalum nitride is deposited using tetrakis(dimethylamino)titanium (TDMAT) and ammonia in a thermal ALD process.

In some embodiments, exposing the substrate to the blocking molecule is repeated after deposition of the barrier layer 790 to regenerate the blocking layer 780. In some embodiments, the barrier layer 790 is deposited again after the blocking layer 780 is regenerated. In some embodiments, exposure of the substrate 705 to a blocking molecule and depositing a barrier layer 790 is repeated until the barrier layer 790 has reached a predetermined thickness.

The exposure to the surface blocking chemistry, or blocking layer 780 regeneration, can be performed once or repeated after a number of deposition cycles or after a predetermined film thickness is formed. In some embodiments, a barrier layer 790 is deposited with a thickness in a range of from about 2 Å to about 200 Å, or in a range of from about 2 Å to about 175 Å or in a range of from about 5 Å to about 175 Å, or in a range of from about 5 Å to about 170 Å, or in a range of from about 5 Å to about 150 Å, or in a range of from about 5 Å to about 100 Å, or in a range of from about 2 Å to about 50 Å, or in a range of from about 2 Å to about 25 Å before the blocking layer 780 is regenerated.

In some embodiments, the barrier layer 790 is conformally deposited on the top surface 761, sidewall 762, lower sidewall 767, bottom surface 768, upper sidewall 769 of the second dielectric layer 760 in the feature 770 and the surface (sidewall 763) of the etch stop layer 750 after formation of the blocking layer 780 on the underlying metal surface (bottom surface 764 of via portion 772). In some embodiments, the barrier layer 790 is deposited on the sidewall 762, sidewall 763 of the via portion 772 and the bottom surface 768 and upper sidewall 769 of the trench portion 774 of the feature 770. In some embodiments, the barrier layer 790 forms on the sidewalls to the blocking layer 780 on the metal surface. In some embodiments, a small gap is formed between the bottom surface 764 of the via portion 772 and the bottom edge of the barrier layer 790 due to the presence of the blocking layer 780.

In the embodiments illustrated in the Figures, the barrier layer 790 is formed on the sidewall 762 of the via portion 772, the lower sidewall 767, bottom surface 768 and upper sidewall 769 of the trench portion 774 of the feature 770. The Figures do not show barrier layer 790 material on the top surface 761 of the second dielectric layer 760. In some embodiments, deposition of the barrier layer 790 results in formation of the barrier layer 790 on the top surface 761 of the second dielectric layer 760. The substrate 705 is then subjected to a process to remove the barrier layer 790 from the top surface 761 of the second dielectric layer 760, for example, by chemical mechanical planarization (CMP).

In one or more unillustrated embodiments, where the blocking layer 780 forms selectively on the metal surface (the bottom surface 764 of the via portion 772) over the dielectric surface (sidewall 762, lower sidewall 767, bottom surface 768, upper sidewall 769, and top surface 761), the barrier layer 790 forms on the blocking layer 780. In specific embodiments where the barrier layer 790 forms on the blocking layer 780, the growth of the barrier layer 790 is advantageously suppressed, and the barrier layer 790 does not form to a thickness greater than or equal to a thickness of the blocking layer 780. Stated differently, the blocking layer 780 has a thickness that is greater than a thickness of the barrier layer 790 on the metal surface (the bottom surface 764 of the via portion 772).

In one or more embodiments, blocking layer 780 formation on clean substrates comprising W, Si, SiO₂ and Al₂O₃ surfaces at different temperatures were subjected to a tantalum nitride deposition process. The tantalum nitride layer formed on each of the surfaces indicated that less than 5 Å of TaN forms on a W surface while greater than 18 Å forms on the Al₂O₃, SiO₂ and Si surfaces after up to 20 deposition cycles. In some embodiments, the blocking layer 780 is reformed on the metal surface after less than or equal to 20 cycles of TaN deposition. In some embodiments, the blocking layer 780 is reformed on the metal surface after less than or equal to 18 cycles of TaN deposition.

In some embodiments, the barrier layer 790 is formed to a thickness in the range of 5 Å to 25 Å without reforming the blocking layer 780. In some embodiments, when 20 Å of tantalum nitride is formed on the dielectric surface and one or more of the aluminum oxide surface or the aluminum nitride surface, less than or equal to 4 Å of tantalum nitride is formed on the metal surface.

Typically, the increase in resistivity of the barrier layer 790 (and the overall device 700) results from a plasma treatment that is used to improve barrier layer and liner properties. However, current plasma treatments damage other layers in the interconnect, such as a low-κ dielectric layer (e.g., the second dielectric layer 760), and increase the capacitance, which degrade overall device performance.

One or more embodiments of the disclosure advantageously provide methods for improving barrier layer 790 and metal liner 792 properties for interconnect structures without using plasma. Advantageously, the methods include using microwave radiation to selectively treat the barrier layer 790 and improve barrier layer 790 and metal liner 792 properties without damaging other layers in the structure, such as a low-κ dielectric layer (e.g., second dielectric layer 760).

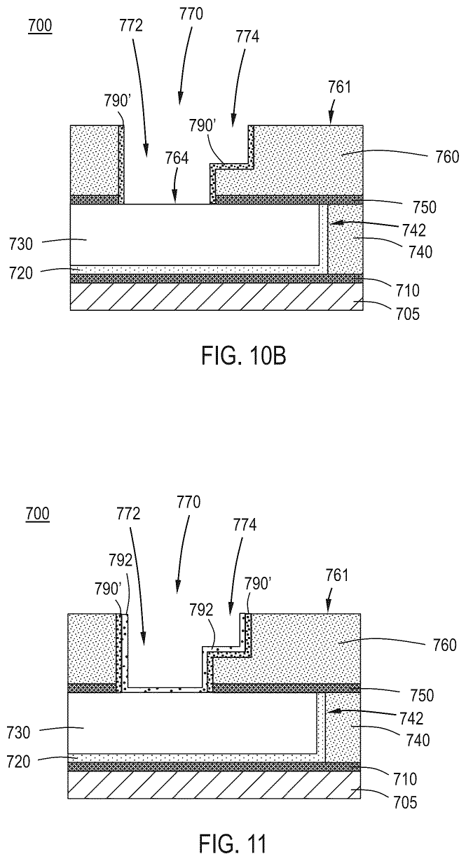

FIG. 10A illustrates a cross-sectional schematic view of the microelectronic device 700 of FIG. 9 after treating the barrier layer 790 to form a treated barrier layer 790′ (operation 14 of method 10 and operation 23 of method 20).

In some embodiments, treating the barrier layer 790 with microwave radiation at operations 14 of method 10 and operation 23 of method 20 comprises exposing the substrate 705, and more specifically, the barrier layer 790, to microwave radiation. As used in this regard, exposing a substrate to “microwave radiation” should be understood to comprise activating a microwave source and exposing the barrier layer 790 to the generated microwave radiation. In one or more embodiments, exposing the substrate to “microwave radiation” includes exposing the substrate to high-frequency electromagnetic radiation without the generation of a plasma (e.g., microwave heating, etc.). As used herein, “high-frequency” electromagnetic radiation includes radio frequency radiation, very-high-frequency radiation, ultra-high-frequency radiation, and microwave radiation. “High-frequency” may refer to frequencies between 0.1 MHz and 300 GHz. In one or more embodiments, treating the barrier layer 790 with microwave radiation at operations 14 of method 10 and operation 23 of method 20 comprises exposing the substrate 705, and more specifically, the barrier layer 790, to microwave radiation that may be generated using any of the processing equipment described herein with respect to FIGS. 1-5.

In some embodiments, treating the barrier layer 790 with microwave radiation at operation 14 of method 10 and operation 23 of method 20 further comprises exposing the barrier layer 790 to a gas flow. In some embodiments, the gas flow is continuous and the microwave exposure is continuous. Stated differently, in some embodiments, neither the gas flow nor the microwave sources are pulsed during the microwave process (e.g., operation 14 of method 10 and operation 23 of method 20).

In some embodiments, the gas flow comprises an inert gas. Without being bound by theory, it is believed that exposure to the inert gas flow may help facilitate removal of volatile reaction byproducts. In some embodiments, the inert gas comprises, consists essentially of, or consists of helium (He) or argon (Ar). In some embodiments, the inert gas comprises, consists essentially of, or consists of a hydrocarbon (e.g., CH₄, C₂H₆, C₂H₄, C₂H₂). In some embodiments, the inert gas comprises, consists essentially of, or consists of CO₂.

In some embodiments, the gas flow comprises a reactant. Without being bound by theory, it is believed that exposure to the reactant gas flow may react with activated oxygen atoms from the barrier layer 790 to form volatile species that are more easily purged from the processing chamber. In some embodiments, the reactant comprises, consists essentially of, or consists of one or more of hydrogen gas (H₂) or carbon monoxide (CO). In some embodiments, the reactant is supplied at a flow rate in a range of about 1 sccm to about 1000 sccm. The skilled artisan will appreciate that the flow rate of the reactant may be optimized based on the pumping speed in the processing chamber and the processing chamber design.

In some embodiments, the methods 10, 20, are performed at relatively low temperatures. The relative low temperatures advantageously result in decreased damage to surrounding materials (e.g., dielectrics). In some embodiments, the substrate 705 is maintained at a temperature in the range of 20° C. to 500° C., or in the range of 150° C. to 450° C. In some embodiments, the substrate 705 is maintained at temperature in a range of about 300° C. to about 400° C. In some embodiments, the substrate 705 is maintained at a temperature of less than or equal to about 300° C. In some embodiments, the substrate 705 is maintained at temperature in a range of about 20° C. to about 50° C. or in a range of about 20° C. to about 100° C.

In some embodiments, the period of exposure to the microwave process (e.g., operation 14 of method 10 and operation 23 of method 20) is controlled to reduce a predetermined depth of the barrier layer 790. In some embodiments, the period is in a range of about 60 seconds to about 600 seconds, in a range of about 60 seconds to about 300 seconds, or in a range of about 30 seconds to about 120 seconds. In some embodiments, the period of exposure to the microwave process is 100 seconds. In embodiments where the period of exposure to the microwave process is 100 seconds, the barrier layer 790 is exposed to the microwave radiation during each barrier layer deposition cycle. In specific embodiments where the period of exposure to the microwave process is 100 seconds, the barrier layer 790 is exposed to the microwave radiation 20 times (e.g., 20 cycles), for a period of 5 seconds per cycle. Stated differently, the barrier layer 790 is treated with the microwave radiation for a period in a range of about 60 seconds (1 minute) to about 600 seconds (10 minutes).

In one or more embodiments, the methods 10, 20 reduce resistivity of the treated barrier layer 790′ compared to a method that treats the barrier layer with a capacitively coupled plasma (CCP) or an inductively coupled plasma (ICP).

In one or more embodiments, the methods 10, 20 reduce a thickness of the barrier layer by less than or equal to 10 Å to 25 Å. In one or more embodiments, the methods 10, 20 reduce a thickness of the barrier layer by 8 Å. As will be explained in further detail below, there is a smaller reduction in thickness of the barrier layer after treatment with microwave radiation compared to treatment with capacitively coupled plasma (CCP) or an inductively coupled plasma (ICP).

In some embodiments, the power of microwave source is in a range of about 800 W to about 8000 W, or in a range of about 900 W to about 5000 W, or in a range of about 1000 W to about 3000 W.

In some embodiments, the pressure of the semiconductor processing chamber may be controlled. In some embodiments, the pressure is maintained in a range of about 1 mTorr to about 10 Torr, or in a range of about 10 mTorr to about 1 Torr, or in a range of about 10 mTorr to about 100 mTorr, or in a range of about 50 m Torr to about 75 m Torr.

FIG. 10B illustrates the microelectronic device 700 of FIG. 10A after removal of the blocking layer 780 (operation 24) to expose the bottom surface 764 of the via portion 772, which is the top surface of the first metal layer 730. The blocking layer 780 can be removed by any suitable technique known to the skilled artisan. The blocking layer 780 is removed after treating the barrier layer 790 to form the treated barrier layer 790′(operations 14 of method 10 and operation 23 of method 20). In some embodiments, removing the blocking layer 780 comprises exposing the blocking layer 780 to a plasma. In some embodiments, the plasma is generated by an inductively coupled plasma (ICP) source, a capacitively coupled plasma (CCP) source, or a remote plasma source. Advantageously, since the blocking layer 780 is removed after treating the barrier layer 790 to form the treated barrier layer 790′, the dielectric surface (sidewall 762, lower sidewall 767, bottom surface 768, upper sidewall 769, and top surface 761) is substantially undamaged by removing the blocking layer 780.

In some embodiments, removing the blocking layer 780 results in a small gap between the top surface of the first metal layer 730 (bottom surface 764 of the via portion 772). This gap is negligible and does not affect subsequent processes. In some embodiments, removal of the blocking layer 780 results in substantially no gap between the top surface of the first metal layer 730 and the bottom edge of the barrier layer 790.

FIG. 11 illustrates the microelectronic device 700 of FIG. 10B after deposition of a metal liner 792 on the treated barrier layer 790′ (operation 25). In some embodiments, the metal liner 792 is selectively deposited on the treated barrier layer 790′ by any suitable deposition process described herein. In some embodiments, the metal liner 792 comprises one or more of ruthenium (Ru), cobalt (Co), molybdenum (Mo), or tantalum (Ta). The metal liner 792 of some embodiments comprises or consists essentially of cobalt (Co). In some embodiments, the metal liner 792 is formed to a thickness in a range of from 5 Å to 25 Å.

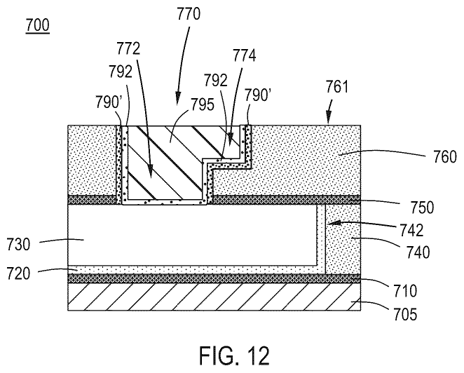

FIG. 12 illustrates the microelectronic device of FIG. 11 after deposition of a second metal layer 795 in the feature 770. More specifically, FIG. 12 illustrates the gapfill process of operation 26 in method 20. In some embodiments, the second metal layer 795 is deposited to fill the gap, i.e., the portion of the feature 770 not bounded by the via portion 772 and the trench portion 774. The second metal layer 795 is formed on the top surface of the first metal layer 730 (bottom surface 764 of the via portion 772). In some embodiments, the second metal layer 795 is formed on a top surface (e.g., on top) of the metal liner 792. The second metal layer 795 may also be referred to as a “gapfill material.” In some embodiments, the gapfill material comprises one or more of copper (Cu), cobalt (Co), molybdenum (Mo), or ruthenium (Ru). In some embodiments, the gapfill material comprises copper (Cu). In some embodiments, the gapfill material consists of copper (Cu). In some embodiments, the gapfill material comprises cobalt (Co). In some embodiments, the gapfill material consists of cobalt (Co). In some embodiments, the gapfill material comprises molybdenum (Mo). In some embodiments, the gapfill material consists of molybdenum (Mo). In some embodiments, the gapfill material comprises ruthenium (Ru). In some embodiments, the gapfill material consists of ruthenium (Ru).

In some embodiments, the gapfill material comprises copper (Cu), the metal liner 792 comprises cobalt (Co), the treated barrier layer 790′ comprises tantalum nitride, the etch stop layer 750 comprises one or more of aluminum oxide aluminum oxide, the second dielectric layer 760 comprises silicon oxide, the first metal layer 730 comprises tungsten, and the second metal layer 795 forms on the top surface of the first metal layer 730 that is exposed through the via portion 772 of the feature 770 and on the metal liner 792.

In embodiments where the metal liner 792 is not present, the second metal layer 795 forms on the top surface of the first metal layer 730 that is exposed through the via portion 772 of the feature 770, the treated barrier layer 790′ on the sidewall 762 of the via portion 772, and on the treated barrier layer 790′ of the lower sidewall 767, bottom surface 768 and upper sidewall 769 of the trench portion 774.

In some embodiments, a blanket deposition process deposits a second metal layer 795 into the feature 770 and on the top surface 761 of the second dielectric layer 760. The second metal layer 795 is formed on the top surface 761 of the second dielectric layer 760 can be removed by any suitable technique including, but not limited to, etching and chemical mechanical planarization (CMP).

One or more embodiments of the disclosure are directed to a non-transitory computer readable medium including instructions, that, when executed by a controller of a processing chamber, cause the processing chamber to perform the operations of method 10. In some embodiments, the non-transitory computer readable medium includes instructions, that, when executed by a controller of a processing chamber, cause the processing chamber to perform the operations of method 20.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A barrier layer comprising tantalum nitride (TaN) was conformally deposited on a dielectric layer on a semiconductor substrate. The dielectric layer comprises at least one feature defining a gap including sidewalls comprising a low-κ dielectric material and a bottom. The barrier layer was deposited at different thicknesses and treated with a capacitively coupled plasma (CCP) at 40 MHz. An amount of resistivity reduction was measured when the barrier layer was deposited at a thickness of about 50 Å, about 100 Å, and greater than 100 Å. When the barrier layer was deposited to about 50 Å, the barrier layer showed a resistivity reduction of about 55% after treating the barrier layer with the CCP 40 MHz for 30 seconds. When the barrier layer was deposited to about 100 Å, the barrier layer showed a resistivity reduction of about 49.5% after treating the barrier layer with the CCP 40 MHz for 30 seconds. When the barrier layer was deposited to greater than 100 Å (about 170 Å), the barrier layer showed a resistivity reduction of about 40.6% after treating the barrier layer with the CCP 40 MHz for 30 seconds.

### Comparative Example 2

A barrier layer comprising tantalum nitride (TaN) was conformally deposited on a dielectric layer on a semiconductor substrate. The dielectric layer comprises at least one feature defining a gap including sidewalls comprising a low-κ dielectric material and a bottom. The barrier layer was deposited at different thicknesses and treated with a capacitively coupled plasma (CCP) at 40 MHz. An amount of low-κ damage and an amount of carbon (C) loss were measured when the barrier layer was treated with CCP at 40 MHz for 30 seconds. The amount of low-κ damage was measured by measuring the dielectric constant of the treated barrier layer using a mercury (Hg) probe technique, which is known to the skilled artisan. Generally, it was observed that the higher the dielectric constant, the greater the amount of low-κ damage present. The dielectric constant of the barrier layer treated with CCP at 40 MHz for 30 seconds was measured at about 3.68. There was about 16% carbon loss (measured using x-ray photoelectron spectroscopy (XPS)) as a result of the treatment with CCP at 40 MHz for 30 seconds.

### Inventive Example 1

A barrier layer comprising tantalum nitride (TaN) was conformally deposited on a dielectric layer on a semiconductor substrate. The dielectric layer comprises at least one feature defining a gap including sidewalls comprising a low-κ dielectric material and a bottom. The barrier layer was deposited at different thicknesses and treated with microwave radiation in accordance with methods 10 and 20. An amount of resistivity reduction was measured when the barrier layer was deposited at a thickness of about 50 Å, about 100 Å, and greater than 100 Å. When the barrier layer was deposited to about 50 Å, the barrier layer showed a resistivity reduction of about 77% after treating the barrier layer with microwave radiation for a total of 10 minutes. When the barrier layer was deposited to about 100 Å, the barrier layer showed a resistivity reduction of about 51% after treating the barrier layer with microwave radiation for a total of 10 minutes. When the barrier layer was deposited at a thickness greater than 100 Å (to about 170 Å), the barrier layer showed a resistivity reduction of about 38% after treating the barrier layer with microwave radiation for a total of 10 minutes. Advantageously, treating the barrier layer with microwave radiation can achieve a greater resistivity reduction (by at least 15% or at least 20%) than is achieved by Comparative Example 1, which includes treating the barrier layer with CCP at 40 MHz for 30 seconds.

### Inventive Example 2

A barrier layer comprising tantalum nitride (TaN) was conformally deposited on a dielectric layer on a semiconductor substrate. The dielectric layer comprises at least one feature defining a gap including sidewalls comprising a low-κ dielectric material and a bottom. The barrier layer was deposited at different thicknesses and treated with microwave radiation in accordance with methods 10 and 20.

An amount of low-κ damage was measured when the barrier layer was treated with microwave radiation for 1 minute and 5 minutes. The amount of low-κ damage was measured by measuring the dielectric constant of the treated barrier layer using a mercury (Hg) probe technique, which is known to the skilled artisan. Generally, it was observed that the higher the dielectric constant, the greater the amount of low-κ damage was present. The dielectric constant of the barrier layer treated with microwave radiation for 1 minute was measured at about 3.15. The dielectric constant of the barrier layer treated with microwave radiation for 5 minutes was measured at about 3.18.

An amount of carbon (C) loss was measured using x-ray photoelectron spectroscopy (XPS) when the barrier layer was treated with microwave radiation for 1 minute, 3 minutes, 5 minutes, and 10 minutes. There was less than 1% carbon loss as a result of the treatment with microwave radiation for 1 minute. There was less than 1.2% carbon loss as a result of the treatment with microwave radiation for 3 minutes. There was less than 1.5% carbon loss as a result of the treatment with microwave radiation for 1 minute. There was less than 3.3% carbon loss as a result of the treatment with microwave radiation for 1 minute. Advantageously, treating the barrier layer with microwave radiation resulted in less low-κ damage and less carbon (C) loss than the treatment with CCP at 40 MHz for 30 seconds.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a microelectronic device, the method comprising:
conformally depositing a barrier layer on a semiconductor substrate; and
treating the barrier layer with microwave radiation to form a treated barrier layer.

2. The method of claim 1, wherein the barrier layer comprises one or more of doped or undoped tantalum nitride (TaₓN_{y}), or doped or undoped titanium nitride (TiₓN_{y}).

3. The method of claim 1, wherein the barrier layer is not exposed to a plasma.

4. The method of claim 1, further comprising exposing the barrier layer to a gas flow while treating the barrier layer with microwave radiation.

5. The method of claim 4, wherein both the gas flow and the microwave radiation are continuous.

6. The method of claim 4, wherein the gas flow comprises a reactant.

7. The method of claim 6, wherein the reactant is supplied at a flow rate in a range of about 1 sccm to about 1000 sccm.

8. The method of claim 6, wherein the reactant comprises hydrogen gas (H₂).

9. The method of claim 1, wherein the semiconductor substrate is maintained at a temperature in a range of about 150° C. to about 400° C.

10. The method of claim 1, wherein the barrier layer is treated with the microwave radiation for a period in a range of from about 1 minute to about 10 minutes.

11. The method of claim 1, wherein the method reduces resistivity of the treated barrier layer compared to a method that treats the barrier layer with a capacitively coupled plasma (CCP) or an inductively coupled plasma (ICP).

12. The method of claim 1, wherein the method reduces a thickness of the barrier layer by less than or equal to 10 Å to 25 Å.

13. A method of forming a microelectronic device, the method comprising:
conformally depositing a barrier layer on a dielectric layer on a semiconductor substrate, the dielectric layer comprising at least one feature defining a gap including sidewalls comprising a low-κ dielectric material and a bottom, the barrier layer forming in the gap along the sidewalls and the bottom; and
treating the barrier layer with microwave radiation to form a treated barrier layer.

14. The method of claim 13, wherein the barrier layer comprises one or more of doped or undoped tantalum nitride (TaₓN_{y}), or doped or undoped titanium nitride (TiₓN_{y}).

15. The method of claim 13, wherein the barrier layer is not exposed to a plasma.

16. The method of claim 13, wherein the low-κ dielectric material is substantially undamaged by the method.

17. The method of claim 13, wherein the method reduces resistivity of the treated barrier layer compared to a method that treats the barrier layer with a capacitively coupled plasma (CCP) or an inductively coupled plasma (ICP).

18. The method of claim 13, wherein the method reduces a thickness of the barrier layer by less than or equal to 10 Å to 25 Å.

19. A method of forming a microelectronic device, the method comprising:
selectively depositing a self-assembled monolayer (SAM) on a dielectric layer on a semiconductor substrate, the dielectric layer comprising at least one feature defining a gap including sidewalls comprising a low-dielectric material and a bottom, the SAM selectively deposited on the bottom of the gap;
depositing a barrier layer in the gap along the sidewalls;
treating the barrier layer with microwave radiation to form a treated barrier layer;
removing the SAM after treating the barrier layer;
depositing a metal liner on the treated barrier layer; and
performing a gap fill process on the metal liner.

20. The method of claim 19, wherein the barrier layer is not exposed to a plasma, and the method reduces resistivity of the treated barrier layer compared to a method that treats the barrier layer with a capacitively coupled plasma (CCP) or an inductively coupled plasma (ICP).
